(19) United States
(12) Patent Application Publication
(10) Pub. No.: US 2026/0033047 A1
(43) Pub. Date: Jan. 29, 2026

(54) MINI LED LIGHT PANEL USED AS DISPLAY AND FILLED WITH REFLECTIVE GEL TO ENHANCE LUMINOSITY AND MINI LED DISPLAY HAVING THE SAME

(71) Applicant: STARLIGHT DISPLAY CORPORATION, HSINCHU CITY (TW)

(72) Inventors: CHIH-CHAO CHANG, HSINCHU CITY (TW); YI-YU TSAI, HSINCHU CITY (TW); YU-CHUN CHENG, HSINCHU CITY (TW)

(21) Appl. No.: 18/780,525

(22) Filed: Jul. 23, 2024

(51) Int. Cl. H01L 33/46; H01L 25/075; H01L 27/15

(52) U.S. Cl. CPC H10H 20/841; H01L 25/0753; H10H 29/142

(57) ABSTRACT

A mini LED light panel used as display and filled with reflective gel to enhance luminosity and a mini LED display of the light panel are disclosed. The light panel includes a substrate, an LED unit, first and second reflective gels. The LED unit includes LEDs having a beam angle greater than or equal to 90 degrees. The LEDs have a length of 25˜500 μm along the X-axis and Y-axis, and a length more than 10 μm along the Z-axis, and the length along the Y-axis is greater than or equal to the length along the X-axis. Each LED unit includes a first light replenishment section formed and sandwiched by the LEDs, and second and third light replenishment sections formed and sandwiched by the LED units adjacent to the X-axis and Y-axis respectively. Therefore, a brightness compensation gain effect with “strong reflection and low interference” can be achieved.

### BACKGROUND OF THE DISCLOSURE

### Technical Field

The present disclosure relates to the field of mini LED products, and more particularly relates to a mini LED light panel used as display and filled with reflective gel to enhance luminosity and its mini LED display, and the mini LEDs with specific dimensions are arranged in the manner that a plurality of gel-filled areas is defined with a correspondence of specific size, so that the reflective gel is set in the appropriate state to achieve the brightness gain by reflection, visually concealing the splicing lines and providing a high brightness compensation effect.

### Description of the Related Art

The LED display technology has evolved to a quite mature level, and the technology development has passed its peak period. With the rise of new-generation LEDs, smaller LED products began to replace the traditional LEDs as a direct light source or backlight source, and thus mini LEDs have become a popular type of LEDs.

In terms of backlight applications, the mini LED board installed in mini LED backlighting products is the main structure used to set up a mini LED chip and plays the role of providing light. The mini LED chip can be set up on a circuit substrate through the packaging process to form a basic mini LED board structure, which can then be designed and customized according to the various display requirements. The design of the mini LED board will have a great impact on the overall display performance and energy consumption, including the intensity of the luminous intensity, the degree of available light energy, and so on. As to the applications for direct display, the mini LEDs can achieve higher brightness, contrast and color accuracy of the display, so the design is inseparable from the consideration of luminous brightness and light color performance. Therefore, although the mini LED has the above advantages, how to make mini LED light panel products (regardless of adopting a backlight or direct light source) achieve high brightness performance, and then make the structure of the display to enhance its color rendering effect is still a research and development direction for related manufacturers.

In view of the above, the present discloser based on years of experience in the related industry to conceive and disclose a mini LED light panel and a mini LED display as display and filled with reflective gel to enhance the luminosity. The mini LED light board and its mini LED display are designed to enhance the light reflective efficiency of the reflective gel and the overall luminosity in combination with the specific condition for light replenishing area under specific LED specifications, so as to enhance the overall brightness of the display in applications.

### SUMMARY OF THE DISCLOSURE

It is a primary objective of the present disclosure to provide a mini LED light panel used as display and filled with reflective gel to enhance luminosity and a mini LED display thereof. Through the limitations of the LED dimensions and beam angle, in conjunction with the specific conditions of the light replenishment section area, the filled reflective gel can realize better reflective performance and thus enhance the brightness performance of the whole light panel and the display.

To achieve the aforementioned objective, the present disclosure provides a mini LED light panel used as display and filled with reflective gel to enhance luminosity, which includes: a substrate; a plurality of LED units, arranged in a matrix of at least 2*2 and disposed on the substrate, wherein the 2*2 means that there are at least two LED units in the X-axis and the Y-axis of the substrate respectively, each LED unit comprises: a first LED; a second LED, installed on a side of the first LED; the first LED and the second LED being arranged in a matrix of 1*2 in the X-axis, wherein the 1*2 means that the first LED and the second LED are arranged in the X-axis; the first LED and the second LED having a beam angle greater than or equal to 90 degrees, each LED unit having one or more emitting light colors based on the light colors of the first LED and the second LED; wherein the length of each first LED and each second LED in the Y-axis is greater than or equal to the length of each first LED and each second LED in the X-axis, and the length of each first LED and each second LED in the Z-axis is more than 10 μm; and at least one first light replenishment section, formed and sandwiched by the first LED and the second LED; at least two second light replenishment sections, formed and sandwiched between any two adjacent LED units in the X-axis; at least two third light replenishment sections, formed and sandwiched between any two adjacent LED units in the Y-axis; wherein each third light replenishment section is greater than each second light replenishment section, and each second light replenishment section is greater than or equal to the first light replenishment section; at least one fourth light replenishment section, formed and sandwiched between the second light replenishment sections and the third light replenishment sections; a first reflective gel, filled in the first light replenishment sections, the second light replenishment sections, the third light replenishment sections and the fourth light replenishment section, wherein the first reflective gel has a reflectivity greater than 50% relative to the light with a wavelength of 420 nm˜700 nm; and a second reflective gel, filled between an edge of the substrate and the adjacent LED units, wherein the second reflective gel has a reflectivity greater than 50% relative to the light with a wavelength of 420 nm˜700 nm; wherein the first reflective gel has a reflectivity relative to the light with a wavelength of 420 nm˜700 nm greater than or equal to the reflectivity of the second reflective gel relative to the light with a wavelength of 420 nm˜700 nm.

Preferably, the length of each first LED and each second LED in the X-axis is 70˜125 μm, the length of each first LED and each second LED in the Y-axis is 115˜230 μm, the area of each of the first light replenishment sections is equal to 0.04˜0.86 times the area of the first LED or the second LED, the area of each of the second light replenishment sections is equal to 0.04˜3.44 times the area of the first LED or the second LED, the area of each of the third light replenishment sections is equal to 0.08˜6 times the area of the first LED or the second LED

Further, the first reflective gel and the second reflective gel are integrally formed. First, reflective gel materials are coated to the LED units, the areas of the second light replenishment sections, the third light replenishment sections and the fourth light replenishment section, and between an edge of the substrate and the adjacent LED units, and then, after adjusting the thickness of the reflective gel materials corresponding to the positions of the first LEDs and the second LEDs, the first reflective gel and the second reflective gel are formed, and the lengths of the first reflective gel and the second reflective gel and the lengths of the first LEDs and the second LEDs in the Z-axis are consistent with each other, so as to provide better convenience for the manufacturing process.

In another implementation mode, further comprises a third LED and two first light replenishment sections, the third LED is installed to a side of the first LED or the second LED and formed and sandwiched to form any one of the first light replenishment sections, and the third LED, the first LED, and the second LED in the X-axis are arranged into a matrix of 1*3, wherein the 1*3 means that the first LED, the second LED and the third LED are arranged in the X-axis, the third LED has a beam angle greater than or equal to 90 degrees, the third LED in the X-axis and in the Y-axis has lengths equal to 25˜500 μm respectively, the length of the third LED in the Y-axis is length greater than or equal to the length of the third LED in the X-axis, the length of the third LED in the Z-axis is more than 10 μm, and the length of the third LED in the Z-axis is consistent with the length of the first LED or the second LED in the Z-axis.

Preferably, the length of each first LED, each second LED and each third LED in the X-axis is 25˜110 μm, the length of each first LED, each second LED and each third LED in the Y-axis is 50˜210 μm, the area of each of the first light replenishment sections is equal to 0.2˜5.4 times the area of the first LED, the second LED or the third LED, the area of each of the second light replenishment sections is equal to 0.2˜57 times the area of the first LED, the second LED or the third LED, and the area of each of the third light replenishment sections is equal to 5˜119 times the area of the first LED, the second LED or the third LED.

Based on the above preferred embodiment, the first reflective gel and the second reflective gel are integrally formed. First, reflective gel materials are coated onto the LED units, the areas of the second light replenishment sections, the third light replenishment sections and the fourth light replenishment section, and between an edge of the substrate and the adjacent LED units, and then, after adjusting the thickness of reflective gel material corresponding to the positions of the first LEDs, the second LEDs, and the third LEDs, the first reflective gel and the second reflective gel are formed, and the lengths of the first reflective gel and the second reflective gel in the Z-axis are consistent with those of the first LEDs and the second LEDs, so as to improve the efficiency, yield rate and convenience of the manufacturing process.

Preferably, the mini LED light panel further includes a protective part, covered on the LED units, the first reflective gel and the second reflective gel, and the protective part having a penetration rate greater than 0.5%, so as to achieve the protective effect.

Preferably, the mini LED light panel further includes a light adjustment part, covered onto the LED units, the first reflective gel and the second reflective gel, and the light adjustment part being a single-layer or multilayer structure, so as to achieve the effects of converting emitting light colors or adjusting luminous status.

Preferably, the mini LED light panel further includes a protective part and a light adjustment part, the light adjustment part being a single-layer or multilayer structure mounted onto the LED units, the first reflective gel and the second reflective gel, and the protective part being covered onto the light adjustment part and having a penetration rate greater than 0.5%.

Based on the above embodiments and the same technical concepts, the present disclosure also provides a mini LED display with visually hidden splicing lines and high brightness compensation. The mini LED display includes a plurality of mini LED light panels of one of the aforementioned types spliced together to form a display panel; and a frame fixed to the periphery of the display panel, so as to form a display panel with excellent display brightness through the characteristics of the mini LED light panels.

In summation of the description above, the present disclosure has disclosed a mini LED light panel used as display and filled with reflective gel to enhance luminosity and a mini LED display of the light panel. Through the limitations of the LED dimensions and beam angle, in conjunction with the specific conditions of the area of the light replenishment sections, the filled first and second reflective gels can reliably reflect the light emitted by the LED to enhance the overall luminosity while eliminating the phenomenon of mutual interference of the reflected light. At the same time, the mini LED display formed by the mini LED light panels spliced with each other can conceal the splicing lines and has the function of high brightness compensation. Further, the present disclosure also provides embodiments showing the detailed technical characteristics of the mini LED light panel and the mini LED display as described in the above paragraphs.

### BRIEF DESCRIPTION OF THE DRAWINGS

FIG. 1 is a schematic view showing the structure of a mini LED light panel in accordance with a first embodiment of the present disclosure;

FIG. 2 is a schematic view showing the formation of a first reflective gel and a second reflective gel of a mini LED light panel in accordance with the first embodiment of the present disclosure;

FIG. 3 is a schematic view showing the structure of a mini LED light panel in accordance with another implementation mode of the first embodiment of the present disclosure;

FIG. 4 is a schematic view showing the structure of a mini LED light panel in accordance with a second embodiment of the present disclosure;

FIG. 5 is a schematic view showing the structure of a mini LED light panel in accordance with another implementation mode of the second embodiment of the present disclosure; and

FIG. 6 is a schematic view showing the structure of a mini LED light panel in accordance with a third embodiment of the present disclosure.

### DETAILED DESCRIPTION OF THE PREFERRED EMBODIMENTS

In the field of Mini LED display technology, Mini LED light panels, which are the main source of light supply, are preferred to have high brightness performance, and in this technology field, there are many structural techniques to fill the gaps with materials such as white glue and black glue after the Mini LEDs are assembled on a circuit substrate. Based on the characteristics of white glue and black glue, experienced people in the industry or people having ordinary skill in the art can generally conclude that white glue reflects light and black glue absorbs light. Therefore, it is not an unprecedented technology to coat Mini LED boards with white glue or black glue. However, due to differences in the type of gel, the arrangement of the Mini LED features and other conditions, the final product will have completely different reflection effects and brightness performance. Therefore, not all Mini LED light panels with gel can have the same light output effect. Therefore, the present discloser disclosed a method of combining the size range of the mini LED itself, the relationship between the area of the specific light replenishment sections and reflectivity conditions of the reflective gel, so that the reflective gel filled in the light replenishment sections and having a specific reflectivity can reflect the light of the mini LED with a specific beam angle, thereby forming an excellent reflection effect, and enhancing the brightness performance of the product. The technical characteristics, dimensions, and proportion of the mini-LED light panel and mini-LED display of the present disclosure will become clearer to those having ordinary skill in the art in light of the following detailed description and the illustrated drawings of illustrative embodiments of the present disclosure. It is intended that the embodiments and figures disclosed herein are to be considered illustrative rather than restrictive.

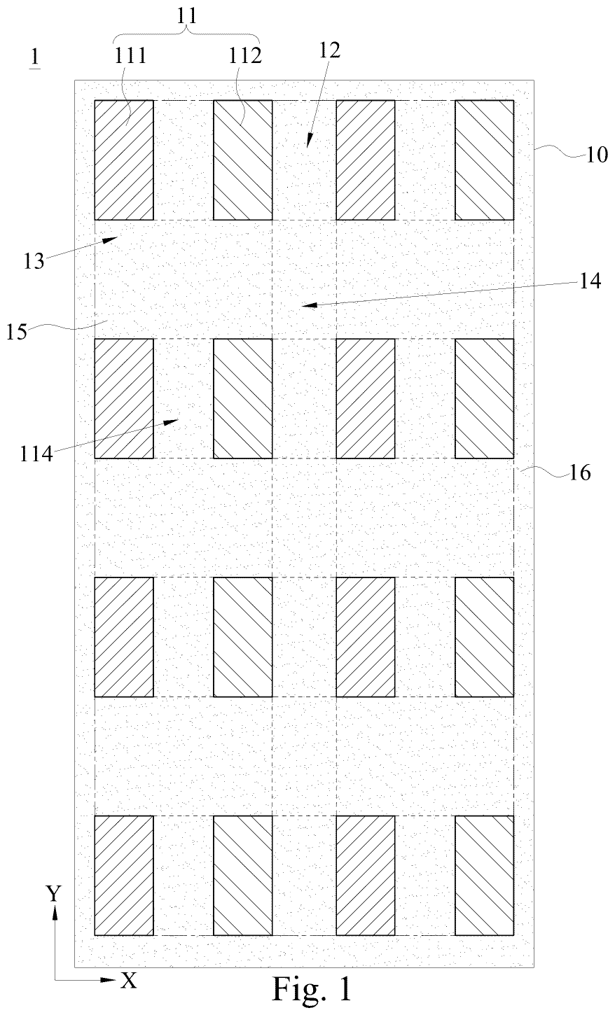

With reference to FIG. 1 for schematic view showing the structure of a mini LED light panel in accordance with a first embodiment of the present disclosure, the mini LED light panel is used as display and filled with reflective gel to enhance luminosity 1, and includes a substrate 10 at least having a first LED 111, a second LED 112 and a plurality of LED units 11 of at least one first light replenishment section, at least two second light replenishment sections 12, at least two third light replenishment sections 13, at least one fourth light replenishment section 14, a first reflective gel 15 and a second reflective gel 16.

The type of the substrate 10 is a board with a circuit design such as a printed circuit board (PCB), and the substrate 10 can be made of a material selected from bismaleimide triazine (BT) resin, ceramics, glass, polyimide (PI), wafer carrier (substrate) board, silicon, metal, etc. Each LED unit 11 is arranged into a matrix of 2*2 and disposed on the substrate 10, and each LED unit 11 at least includes the first LED 111, the second LED 112 and the first light replenishment section 114. Since the present disclosure is related to the mini LED light panel, therefore the type of the first LED 111 and the second LED 112 is the mini LED. In this embodiment, the LED units 11 arranged in the matrix of 2*4 is disposed on the substrate 10, but it is a preferred embodiment intended for illustrating the present disclosure only. Various electronic components such as driver ICs, passive components and connectors may be further bonded and installed on the side opposite to the LED units 11 of the substrate 10 according to application requirements. However, this is well-known art in the field of light panel driver technology and not the technical focus of the present disclosure, so it will not be described in detail here.

The first LED 111 and the second LED 112 of each LED unit 11 in the X-axis arranged into the matrix of 1*2 matrix, wherein the beam angle of the first LED 111 and the second LED 112 is greater than or equal to 90 degrees, and each LED unit 11 has one or more emitting light color based on the light colors of the first LED 111 and the second LED 112; wherein the length of each first LED 111 and each second LED 112 in the X-axis and in the Y-axis are 25˜500 μm respectively, the length of each first LED 111 and each second LED 112 in the Y-axis is greater than or equal to the length of each first LED 111 and each second LED 112 in the X-axis, and the length of each first LED 111 and each second LED 112 in the Z-axis is more than 10 μm. The first light replenishment section 114 is formed and sandwiched by the first LED 111 and the second LED 112, and the area of the first light replenishment section 114 is equal to 0.02˜1 times the area of the first LED 111 or the second LED 112. It is noteworthy that traditional large LEDs and micro LEDs of the latest technology are not applicable to the types of LEDs described in the present disclosure. The traditional large LEDs are limited by their own size and cannot be arranged to form the above-mentioned small spacing and distance settings. Micro LEDs and mini LEDs are completely different in scale and by their size and cannot be arranged into the configuration with small spacing and distance as mentioned above, and micro LED and mini-LED are of completely different scales, where the technology of micro LEDs aims to reduce the spacing between themselves as much as possible, so it is impossible to meet the area configuration of the present disclosure. In other words, the traditional large LED and the micro LED are of the technical field completely different from that of the present disclosure in terms of display applications.

Preferably, the first LEDs 111 and the second LEDs 112 are red, green or blue mini LEDs, so that each LED unit 11 forms a one or more output lights according to the selected light color. In practice, each LED unit 11 does not need to have the same emitting light color. For example, the first LED in any LED unit 11 may be a red LED with a light emission wavelength of 620-640 nm, and the second LED 112 may be a green LED with a light emission wavelength of 520-540 nm. In another LED unit 11 adjacently arranged in the Y-axis, the first LED 111 may be a green LED, the second LED 112 may be a blue LED with a light emission wavelength of 460˜480 nm.

The second light replenishment sections 12 is formed and sandwiched by any two adjacent LED units 11 in the X-axis, and the area of each of the second light replenishment sections 12 is equal to 0.02˜5.8 times the area of the first LED 111 or the second LED 112. The third light replenishment sections 13 is formed and sandwiched by any two adjacent LED units 11 in the Y-axis, and the area of each of the third light replenishment sections 13 is equal to 0.2˜6 times the area of the first LED 111 or the second LED 112; wherein each third light replenishment section 13 is greater than each second light replenishment section 12, and each second light replenishment section 12 is greater than or equal to the first light replenishment section 114. The first reflective gel 15 is filled in the first light replenishment sections 114, the second light replenishment sections 12, the third light replenishment sections 13 and the fourth light replenishment section 14, wherein the first reflective gel 15 has a reflectivity greater than 50% relative to the light with a wavelength of 420 nm˜700 nm. The second reflective gel 16 is filled between an edge of the substrate 10 and the adjacent LED units, between an edge of the substrate 10 and the second light replenishment sections 12, and between an edge of the substrate 10 and the third light replenishment section 13, the second reflective gel 16 has a reflectivity greater than 50% relative to the light with a wavelength of 420 nm˜700 nm. Wherein, the first reflective gel 15 has a reflectivity relative to the light with a wavelength of 420 nm˜700 nm greater than or equal to the reflectivity of the second reflective gel 16 relative to the light with a wavelength of 420 nm-700 nm. With these conditions, the phenomenon of mutual interference of reflected light can be avoided after the intensity of reflection is enhanced, thus achieving the luminous brightness effect with “strong reflection, and low interference”.

Preferably, the first reflective gel 15 and the second reflective gel 16 have a reflectivity such as 60%, 70%, or more than 80% relative to the light with a wavelength of 420 nm˜700 nm.

In particular, it is emphasized that the dimension relationship between each first light replenishment section 114, each second light replenishment section 12, and each third light replenishment section 13 as well as the fourth light replenishment section 14 formed and sandwiched by the light replenishment sections are of great significance in the configuration. By the above-mentioned configuration of dimensions, the brightening performance of reflection can be truly enhanced after the first reflective gel 15 is filled, so that the mini LED light panel 1 has an excellent reflective effect, greatly improving the overall luminosity.

More specifically, the mini LED light panel 1 integrates the technical characteristics including the conditions of individual dimension of the first LED 111 and the second LED 112 in each LED unit 11, the area relationship of the first light replenishment section 114, the second light replenishment sections 12, and the third light replenishment sections 13 formed and sandwiched by the LED units 11, and the properties of the first reflective gel 15 and the second reflective gel 16, such that after the first reflective gel 15 is filled into the light replenishment sections, the light emitted from the LED units 11 can be reflected to achieve the effect of enhancing luminosity. The mini LED light panel 1 further adopts the first LEDs 111 and the second LEDs 112 with a beam angle greater than or equal to 90 degrees, so that the light can actually touch the first reflective gel 15 and/or the second reflective gel 16 and be reflected to the outside, so as to further avoid the situation where the beam angle is too small and the light cannot touch the reflective gel at all beam angle. In addition, the first reflective gel 15 and the second reflective gel 16 of the mini LED light panel 1 also have a reflectivity greater than 50% relative to the light with a wavelength of 420 nm˜700 nm, while the first reflective gel 15 relative to the light with a wavelength of 420 nm˜700 nm has a reflectivity greater than or equal to the reflectivity of the second reflective gel 16 relative to the light with a wavelength of 420 nm˜700 nm, so as to enhance the light reflection effect, avoid the phenomenon of reflected lights interfering with each other after the reflection of high intensity, and achieve the brightness performance with “strong reflection and low interference”. Combining the technical characteristics above. the mini LED light panel 1 can achieve the purpose and effect of reflecting light to increase the overall brightness.

Please refer to the experimental results below. The experiment is performed based on the conditions of the above-mentioned light replenishment sections mini LED light panel 1 which are filled with a reflective gel having a reflectivity greater than 50% relative to the light with a wavelength of 420 nm˜700 nm. The mini LED light panel 1 can enhance the brightness of each light color under different grayscale requirements.

| Gray Level 50 | White Light | Red Light | Green Light | Blue Light |
|---|---|---|---|---|
| With reflective gel | 100% | 100% | 100% | 100% |
| Without reflective gel | 158% | 123% | 187% | 196% |
| Gray Level 150 | White Light | Red Light | Green Light | Blue Light |
| Without reflective gel | 100% | 100% | 100% | 100% |
| With reflective gel | 165% | 125% | 177% | 187% |
| Gray Level 255 | White Light | Red Light | Green Light | Blue Light |
| Without reflective gel | 100% | 100% | 100% | 100% |
| With reflective gel | 155% | 116% | 181% | 200% |

It can be seen from the above results that after the reflective gel is filled, the mini LED light panel 1 can indeed achieve a better brightness effect than the state without the reflective gel in applications of various light colors, and can indeed achieve the effect of enhancing brightness.

Further, in view of the fact that the area of the LED can also be a condition that affects overall reflection and overall luminosity, the present disclosure further discloses that under the optimal lengths of the LEDs in the X-axis and the Y-axis, the first light replenishment section 114, the second light replenishment sections 12 and the third light replenishment sections 13 have an appropriate proportion in area relative to the first LED 111 or the second LED 112, the mini LED light panel 1 can achieve an excellent brightness enhancement effect. In a preferred embodiment of the practical application, the length of each first LED 111 and each second LED 112 in the X-axis is 70˜125 μm, the length of each first LED 111 and each second LED 112 in the Y-axis is 115˜230 μm, and the area of each of the first light replenishment sections 114 is equal to times 0.04˜0.86 of the area of the first LED 111 or the second LED 112, the area of each of the second light replenishment sections 12 is equal to 0.04˜3.44 times the area of the first LED 111 or the second LED 112, and the area of each of the third light replenishment sections 13 is equal to 0.08˜6 times the area of the first LED 111 or the second LED 112, and these configurations create the best structural state for light reflection and enhance luminous brightness.

A series of implementation modes for the application of the mini LED light panel in accordance with this embodiment is shown below. With reference to Tables 1-1 and 1-2 for the preferred length of the first LED 111/the second LED 112 in the X-axis and Y-axis, the first light replenishment section 114, the second light replenishment section 12 and the third light replenishment section 13 in the X-axis and the Y-axis, and the area proportion of the first light replenishment section 114, the second light replenishment section 12 and the third light replenishment section 13 and the first LED 111/the second LED 112 (vs. the column of LED). Since the fourth light replenishment section 14 is formed and sandwiched by the second light replenishment sections 12 and the third light replenishment sections 13, therefore after the area ratio of the second light replenishment sections 12 to the third light replenishment sections 13 is confirmed, the fourth light replenishment section 14 will be formed naturally, so that the dimensions of the fourth light replenishment section 14 are no longer provided here.

TABLE 1-1

| | First LED/ | | | First Light | | | |
|---|---|---|---|---|---|---|---|
| | Second LED | | | Replenishment Section | | | |
| | X | Y | Area | X | Y | Area | vs. |
| Group | (um) | (um) | (um\hat{ }2) | (um) | (um) | (um\hat{ }2) | LED |
| Group 1 | 100 | 200 | 20,000 | 60 | 200 | 12,000 | 60.0% |
| Group 2 | 75 | 125 | 9,375 | 55 | 125 | 6,875 | 73.3% |
| Group 3 | 125 | 230 | 28,750 | 5 | 230 | 1,150 | 4.0% |

TABLE 1-2

| | Second Light | | | | Third Light | | | |
|---|---|---|---|---|---|---|---|---|
| | Replenishment Section | | | | Replenishment Section | | | |
| | X | Y | Area | vs. | X | Y | Area | vs. |
| Group | (um) | (um) | (um\hat{ }2) | LED | (um) | (um) | (um\hat{ }2) | LED |
| Group 1 | 60 | 200 | 12,000 | 60.0% | 260 | 120 | 31,200 | 156.0% |
| Group 2 | 55 | 125 | 6,875 | 73.3% | 205 | 135 | 27,675 | 295.2% |
| Group 3 | 5 | 230 | 1,150 | 4.0% | 255 | 30 | 7,650 | 26.6% |

According to the area proportion of the first light replenishment section 114, the second light replenishment section 12 and the third light replenishment section 13 and the area ratio of the first LED 111 to the second LED 112 as shown in Table 1-1 and Table 1-2, the first reflective gel 15 can provide an excellent light reflection performance after being filled to allow the mini LED light panel 1 to have an extremely high luminosity.

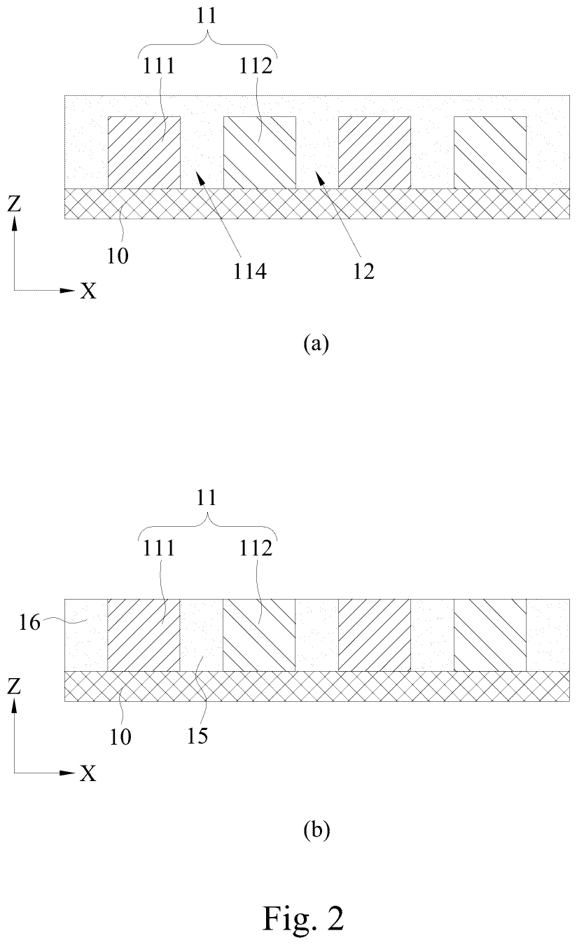

In FIGS. 1 and 2, FIG. 2 shows the formation of the first reflective gel and the second reflective gel of a mini LED light panel in accordance with an embodiment of the present disclosure, the first reflective gel 15 and the second reflective gel 16 are integrally formed. First, reflective gel materials coated onto the LED units 11, the areas of the second light replenishment sections 12, the third light replenishment sections 13 and the fourth light replenishment section 14 and between an edge of the substrate 10 and the adjacent LED units 11, and then, after adjusting the thickness of the reflective gel materials corresponding to the positions of the first LEDs 111 and the second LEDs 112, the first reflective gel 15 and the second reflective gel 16 are formed, and the lengths of the first reflective gel 15 and the second reflective gel 16, and the first LEDs 111 and the second LEDs 112 in the Z-axis are consistent with each other, so that the manufacturing process has better efficiency, yield rate and convenience. The term “consistent” mentioned above refers that the lengths of the first reflective gel 15 and the second reflective gel 16 in the Z-axis can be slightly greater than, equal to, or slightly smaller than the length of the first LED 111 and the second LED 112 in the Z-axis. In response to the size limitations of mini LEDs, the lengths of the first reflective gel 15 and the second reflective gel 16 in the Z-axis can be slightly greater than the length of the first LEDs 111 and the second LEDs 112 in the Z-axis, but they cannot be greater than +10 μm. With reference to FIG. 2, FIG. 2 (a) shows a reflective gel material coated onto the LED units 11, the areas of the second light replenishment sections 12, the third light replenishment sections 13 and the fourth light replenishment section 14 and between an edge of the substrate 10 and the adjacent LED units 11; and FIG. 2 (b) shows the status after adjusting the positions of the first LEDs 111 and the second LEDs 112 to change the thickness of the reflective gel material, wherein the adjustment can be made by grinding. The reflective gel material disposed in the first light replenishment sections 114, the second light replenishment sections 12, the third light replenishment sections 13 and the fourth light replenishment sections 14 is the first reflective gel 15, the reflective gel material disposed between an edge of the substrate 10 and the adjacent LED units 11 is the second reflective gel 16, and the lengths of the first reflective gel 15 and the second reflective gel 16 of this embodiment and the height of the first LED 111 and the second LED 112 in the Z-axis are equal in this embodiment.

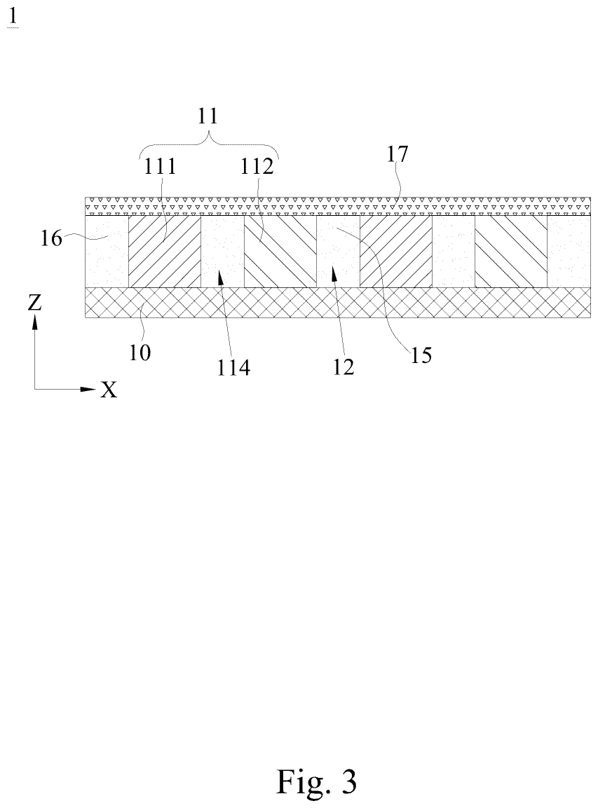

In FIGS. 1, 2 and 3, FIG. 3 shows the structure of a mini LED light panel in accordance with another implementation mode of an embodiment of the present disclosure. In order to enhance the protective effect of the overall structure, the mini LED light panel further includes a protective part 17, covered onto the LED units 11, the first reflective gel 15 and the second reflective gel 16, and the protective part 17 has a penetration rate greater than 0.5%. The protective part 17 is provided for protecting the LED units 11, and it can be in the form of a glass sheet or film, a glue, a liquid crystal, etc. Taking into account the application requirements for display, the protective part 17 also has some properties that may affect the aforementioned light transmittance conditions, and thus the light transmittance can be adjusted to be greater than 0.6%, or 1%, etc. in order to adjust the light on the display to a state. FIG. 3 shows the status of the protective part 17, provided that the lengths of the first reflective gel 15 and the second reflective gel 16 in the Z-axis are equal to those of the first LEDs 111, the second LEDs 112 and the third LEDs 113. Of course, the protective part 17 can also be applied to the implementation mode, where the lengths of the first reflective gel 15 and the second reflective gel 16 in the Z-axis are slightly greater than or slightly smaller than the lengths of the first LEDs 111, the second LEDs 112 and the third LEDs 113 in the Z-axis.

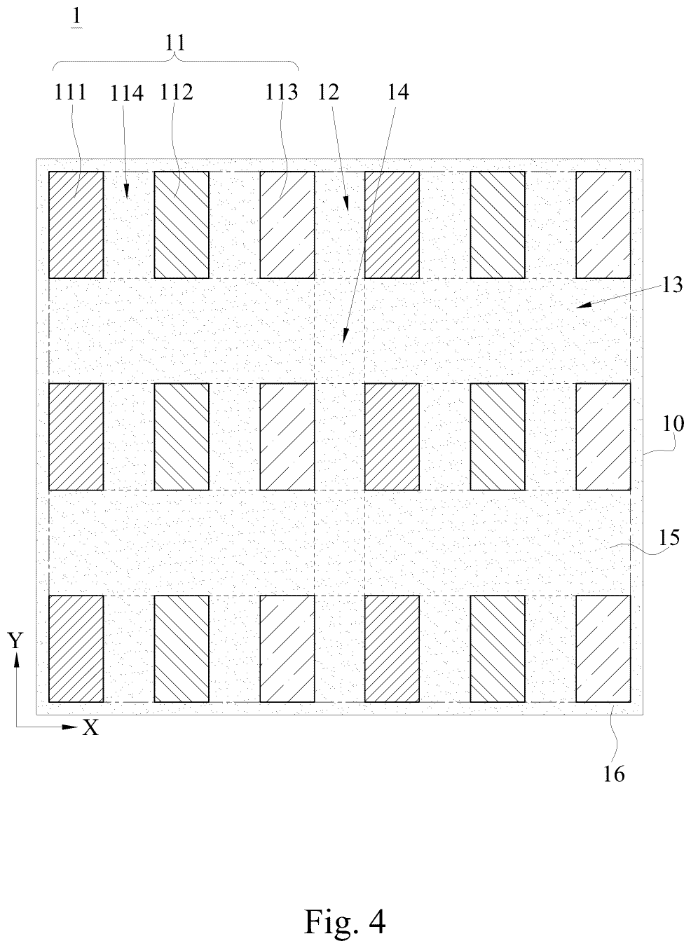

Please continue to refer to FIG. 4, and refer to FIG. 2 again. FIG. 4 shows the structure of a Mini LED light panel according to another embodiment of the present disclosure. Based on the same technical concept, the present disclosure further discloses the second embodiment of the mini LED light panel 1, whose structure is substantially the same as that of the previous embodiment, except that each LED unit 11 of this embodiment further includes a third LED 113 and two first light replenishment sections 114, and the third LED 113 is installed on a side of the first LED 111 or the second LED 112, and sandwiched to form any one of the first light replenishment sections 114, and the third LED 113, the first LED 111, and the second LED 112 in the X-axis are arranged into a matrix of 1*3, the third LED 113 has a beam angle greater than or equal to 90 degrees, the lengths of the third LED 113 in the X-axis and in the Y-axis are respectively 25˜500 μm, and the length of the third LED 113 in the Y-axis is greater than or equal to the length of the third LED 113 in X-axis, the length of the third LED 113 in the Z-axis is more than 10 μm, and the length of the third LED 113 in the Z-axis is consistent with the length of the first LED 111 or the second LED 112 in the Z-axis. Similarly, the term “consistent” means that the length of the third LEDs 113 in the Z-axis can be slightly greater than, equal to, or slightly smaller than the length of the first LED 111 or the second LED 112 in the Z-axis, and based on the limitation of special dimensions of the mini LED, the length of the third LEDs 113 in the Z-axis is slightly greater than the length of the first LEDs 111 or the second LEDs 112 in the Z-axis, but not greater than +10 μm. In this embodiment, the LED units 11 further includes the third LED 113 to form a group of three LED units 11, and the second light replenishment sections 114 of each LED unit 11 are the area formed and sandwiched by the first LED 111, the second LED 112 and the third LED 113. In an implementation mode, the first LED 111 can be a red LED with an emission wavelength of 620˜640 nm, the second LED 112 can be a green LED with an emission wavelength of 520˜540 nm, and the third LED 113 is a green LED with an emission wavelength of 460˜480 nm. The technical characteristics of the second light replenishment sections 12, the third light replenishment sections 13, the fourth light replenishment section 14, the first reflective gel 15 and the second reflective gel 16 are the same as those of the previous embodiment, and thus will not be repeated here.

The present disclosure further discloses another implementation mode of a mini LED light panel 1 with the aforementioned technical characteristics, and the first reflective gel 15 and the second reflective gel 16 can achieve excellent light reflection performance, which in turn can help to enhance the overall luminosity. The rest of technical characteristics and further effects are the same as those of the previous embodiment described above, and thus will not be repeated here.

Similarly, in the configuration with the third LED 113, the present disclosure also discloses that the appropriate area proportions for the first light replenishment section 114, the second light replenishment sections 12 and the third light replenishment sections 13 of the LEDS relative to the first LED 111 or the second LED 112 in the X-axis and in the Y-axis length. Specifically, in an embodiment with the above structural configuration, the length of each first LED 111, each second LED 112 and each third LED 113 in the X-axis is 25˜110 μm, the length of each first LED 111, each second LED 112 and each third LED 113 in the Y-axis is 50˜210 μm, and the area of each of the first light replenishment sections 114 is equal to 0.2˜5.4 times the area of the first LED 111, the second LED 112 or the third LED 113, the area of each of the second light replenishment sections 12 is equal to 0.2˜57 times the area of the first LED 111, the second LED 112 or the third LED 113, and the area of each of the third light replenishment sections 13 is equal to 5˜119 times of the area of the first LED 111, the second LED 112 or the third LED 113, so as to form a structural status with the best light reflection and the enhanced luminosity.

In this embodiment, an application of several groups of mini LED light panels are used for illustrating the present disclosure. Tables 1-3 and 1-4 list the lengths of the first LED 111/the second LED 112/the third LED 113 in the X-axis and the Y-axis, the values of preferred side lengths of the first light replenishment section 114, the second light replenishment section 12 and the third light replenishment section 13 in the X-axis and in the Y-axis, and the first light replenishment section 114, the second light replenishment section 12 and the proportion of the areas of the third light replenishment section 13 to the first LED 111/the second LED 112/the third LED 113 (vs. the column of LED). Similarly, the fourth light replenishment section 14 is formed and sandwiched by the second light replenishment sections 12 and the third light replenishment sections 13, so that after the proportion of the areas of the second light replenishment sections 12 and the third light replenishment sections 13 is confirmed, the fourth light replenishment section 14 is formed naturally, and thus the dimension specifications of the fourth light replenishment section 14 is not listed here.

TABLE 1-3

| | First LED/Second | | | First Light | | | |
|---|---|---|---|---|---|---|---|
| | LED/Third LED | | | Replenishment Section | | | |
| | | | Area | | Y | Area | vs. |
| Group | X (um) | Y (um) | (um\hat{ }2) | X (um) | (um) | (um\hat{ }2) | LED |
| Group 1 | 100 | 200 | 20,000 | 60 | 200 | 12,000 | 60.0% |
| Group 2 | 75 | 180 | 13,500 | 85 | 180 | 15,300 | 113.3% |
| Group 3 | 75 | 125 | 9,375 | 85 | 125 | 10,625 | 113.3% |
| Group 4 | 75 | 125 | 9,375 | 30 | 125 | 3,750 | 40.0% |
| Group 5 | 25 | 50 | 1,250 | 5 | 50 | 250 | 20.0% |
| Group 6 | 100 | 200 | 20,000 | 100 | 200 | 20,000 | 100.0% |

TABLE 1-4

| | Second Light | | | | Third Light | | | |
|---|---|---|---|---|---|---|---|---|
| | Replenishment Section | | | | Replenishment Section | | | |
| | X | Y | Area | vs. | X | Y | Area | vs. |
| Group | (um) | (um) | (um\hat{ }2) | LED | (um) | (um) | (um\hat{ }2) | LED |
| Group 1 | 60 | 200 | 12,000 | 60.0% | 420 | 280 | 117,600 | 588.0% |
| Group 2 | 85 | 180 | 15,300 | 113.3% | 395 | 300 | 118,500 | 877.8% |
| Group 3 | 85 | 125 | 10,625 | 113.3% | 395 | 355 | 140,225 | 1495.7% |
| Group 4 | 30 | 125 | 3,750 | 40.0% | 285 | 190 | 54,150 | 577.6% |
| Group 5 | 1,415 | 50 | 70,750 | 5660.0% | 85 | 1,450 | 123,250 | 9860.0% |
| Group 6 | 1,000 | 200 | 200,000 | 1000.0% | 500 | 1,300 | 650,000 | 3250.0% |

Following the previous embodiment, various detailed technical features may be further added in this embodiment similarly. For example, the first reflective gel 15 and the second reflective gel 16 are integrally formed. First, reflective gel materials are coated onto the LED units 11, the areas of the second light replenishment sections 12, the third light replenishment sections 13 and the fourth light replenishment section 14 and 10 between an edge of the substrate 10 and the adjacent LED units 11, and then, after adjusting the thickness of the reflective gel materials corresponding to the positions of the first LEDs 111, the second LEDs 112, and the third LEDs 113, the first reflective gel 15 and the second reflective gel 16 are formed, and the lengths of the first reflective gel 15 and the second reflective gel 16 are consistent with the length of the first LEDs 111 and the second LEDs 112 in the Z-axis as shown in FIG. 2. The detailed description of the technical characteristics and the corresponding effects are the same as those described in the previous embodiment, and thus will not be repeated here.

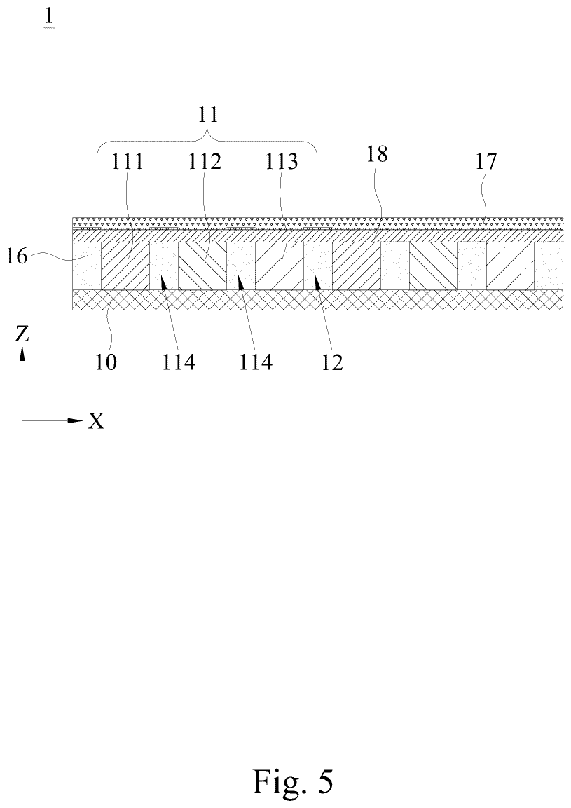

With reference to FIG. 5 for schematic view showing the structure of a mini LED light panel in accordance with another implementation mode of the second embodiment of the present disclosure, the mini LED light panel 1 further includes a light adjustment part 18 which is a single-layer or multilayer structure covered onto the LED units 1, the first reflective gel 15 and the second reflective gel 16, and provided for changing the emitting light color or adjusting the light status, or the mini LED light panel 1 further includes a protective part 17 and a light adjustment part 18, wherein the light adjustment part 18 is a single-layer or multilayer structure installed onto the LED units 11, the first reflective gel 15 and the second reflective gel 16, and the protective part 17 is covered onto the light adjustment part 18, and the protective part 17 has a penetration rate greater than 0.5%. Same as the previous embodiment, the protective part 17 is provided for protecting the LED units 11, and it can be made of a glass board, glass sheet, film, glue, or liquid crystal, etc. Considering the application requirements of the display, the protective part 17 also possesses some characteristics of the effect on light through the aforementioned condition of light transmittance. Same as the previous embodiment, the protective part 17 is provided for protecting the LED units 11 and whose material or structure can be selected to provide the effect of producing auxiliary effects in subsequent display. The rest of technical characteristics and further effects are the same as those of the previous embodiment described above, and thus will not be repeated here. As described above, the light adjustment part 18 may be a single-layer or multilayer structure provided for changing the light color or adjusting the light path, such that the mini LED light panel 1 can have more diversified light performance to meet the application requirements. In this implementation mode, the mini LED light panel 1 includes the protective part 17 and the light adjustment part 18.

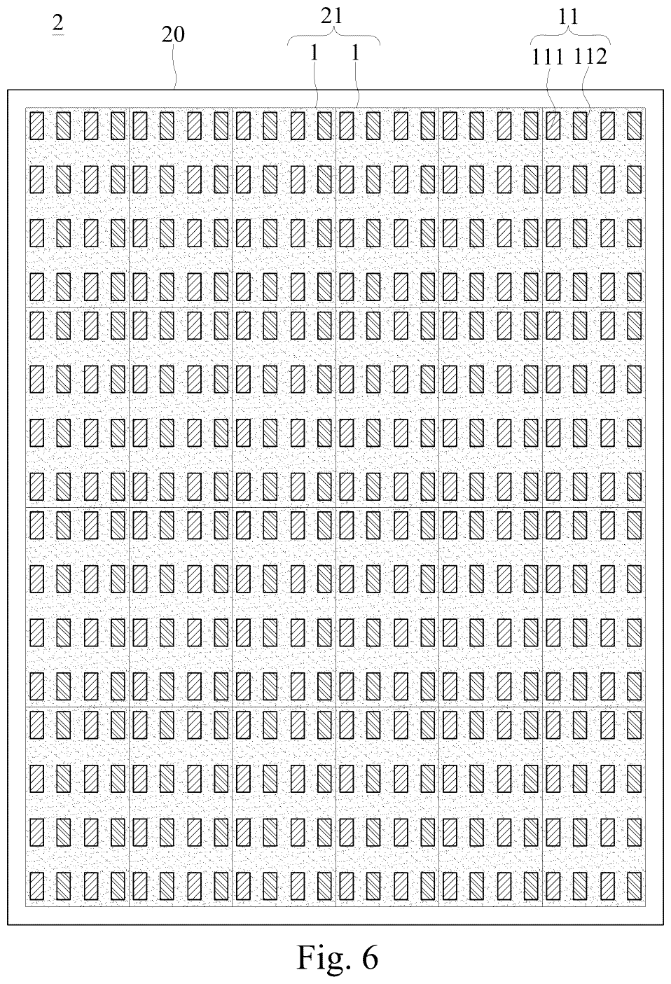

Please continue to refer to FIGS. 1˜6, wherein FIG. 6 is a schematic view showing the structure of a mini LED light panel in accordance with a third embodiment of the present disclosure, and the present disclosure also discloses a mini LED display mini LED display with visually concealed splicing lines and high brightness compensation, which includes a plurality of mini LED light panels 1 and a frame 20, the mini LED light panels 1 are spliced together to form a display panel 21, and the frame 20 is mounted onto the periphery of the display panel 21. The specific technical characteristics of the mini LED light panels 1 are the same as those of the aforementioned embodiments, and each mini LED light panel 1 includes the substrate 10, the LED units 11, the second light replenishment sections 12, the third light replenishment sections 13, the fourth light replenishment section 14, the first reflective gel 15 and the second reflective gel 16. The dimensions and the luminous angles of the first LEDs 111, the second LEDs 112, the first LEDs 111, the second LEDs 112, and the third LEDs 113, and the size relationship between the first light replenishment section 114, the second light replenishment sections 12, the third light replenishment sections 13, and the proportion of the areas of the first LEDs 111, the second LEDs 112, and the third LEDs 113 are the same as those of the previous embodiments.

Through the structural features of the mini LED light panels 1, the light emitted by the LED units 11 is effectively reflected by the first reflective gel 15 and the second reflective gel 16, so that the brightness of the mini LED display 2 during application can be greatly enhanced. In particular, when using a display formed by splicing a plurality of light panels, the viewing angle must be considered. In addition to the front viewing, it must also have good quality for the side viewing at a wide angle. However, in the past, when viewed from the side, the display is formed by splicing the light panels, the splicing seams often easily distort the color emitted by the LED, making it easier for human eyes to detect the presence of the obvious seams. Therefore, this kind of display needs to overcome the problem that the seam between the light panels is clearly seen by human eyes, thus affecting the visual effect and quality, in order to prevent the color distortion of the LEDs. Accordingly, the mini LED display 2 of the present disclosure can solve the problem through the second reflective gel 16. After the mini LED light panels 1 are spliced to each other, the seams of the mini LED light panels 1 are filled with the second reflective gel 16 respectively. Therefore, when the LED units 11 are turned on, the second reflective gel 16 can reflect light, making it difficult for the human eyes to see the seams clearly, and preventing the LED light color from being distorted. For the other technical characteristics of the mini LED light panels 1, various technical characteristics and corresponding functions can be further added as described in the above paragraphs and illustrated in the corresponding diagrams, and thus they will not be repeated here.

In summation of the description above, the mini LED light panel used as display and filled with reflective gel to enhance luminosity and the mini LED display of the present disclosure define the first to third light replenishment sections with a specific size relationship through specific LED specification conditions, so that after the first reflective gel is filled and arranged, an excellent light reflection effect can be achieved and the light emitted by each LED can be reflected by the first reflective gel, thereby greatly improving the overall luminosity and achieving a better utilization rate of the light. The first LEDs, the second LEDs, and the third LEDs located at the edge can reflect light through the second reflective gel. At the same time, the second reflective gel also has the function of preventing the human eyes from directly seeing the seams when the mini LED light panels are spliced together to form the display panel. In addition, the first reflective gel and the second reflective gel selected by the present disclosure must also meet the conditions of the reflectivity greater than 50% for the light with a wavelength of 420 nm˜700 nm and the reflectivity greater than or equal to the second reflective gel, so as to provide the excellent light reflection effect and eliminate the interference of the reflected light. Furthermore, the beam angles of the first LEDs, the second LEDs and the third LEDs must be greater than or equal to 90 degrees to ensure that the emitted light can be reflected by the first reflective gel and the second reflective gel. Combining the above technical characteristics, the mini LED light panels can achieve the effect of brightness compensation through reflection and improve the overall luminosity performance, and the mini LED display formed by splicing the mini LED light panels has the advantages of visually concealed splicing lines and high brightness compensation.

It is here reiterated that the present discloser has been profoundly involved in the related field for many years and is familiar with the technical means of using white glue or black glue to fill the gaps between the mini LEDs. However, the light panels filled with glue will still produce very different light output performances under different structural designs, LED conditions or glue materials, since there are many variables that affect the light regulation performance such as light reflection or absorption. From the design perspective of the relative relationship between the glue and the LED, there have been many technical means proposed in the past to limit the ratio of the height of the glue filled to the height of the LED. In other words, in three-dimensional space, the glue filling state in the Z-axis is emphasized to achieve the desired effect, and the structural design in other axes is not given much attention. The present disclosure has developed a completely different structural design to allow the gel to provide the best reflective effect. The technical means proposed based on the development concept are the above-mentioned mini LED light panel and its technical characteristics. The present disclosure is designed mainly for the X-Y plane, defining the first to fourth light replenishment sections. At the same time, the LEDs of the present disclosure also have restrictions on the size and beam angle. After the first reflective gel and the second reflective gel with specific reflectivity conditions and relationships are filled, combined with the conditional characteristics of LEDs, it can effectively and reliably produce the excellent “strong reflection and low interference” effects, thus achieving the objective of increasing the luminosity. Therefore, it is obvious that the technical focus of the present disclosure is not only to emphasize filling or using reflective gel, but how to make the reflective gel play its best reflective performance. For this, the specific technical means is to use the first to third light replenishment sections with a specific area relationship and the fourth light replenishment section formed and sandwiched by the LEDs, the specific reflectivity of the gel and the LED with a specific beam angle and size, in order to further increase and enhance the reflective performance. It can be seen that the restrictions on the dimensions and characteristic of each element of the present disclosure are not features that can be easily conceived and solved based on the related art, but have clear purposes and achievable effects. In other words, compared with various related technologies that do not regulate the size of seams on the X-Y plane, the light panel and display of the present disclosure not only have technical characteristics s that cannot be easily conceived and solved, but also have unexpected effects, and provide an excellent new product for the display industry.

What is claimed is:

1. A mini LED light panel used as a display and filled with reflective gel to enhance luminosity, comprising:
a substrate;
a plurality of LED units arranged in a matrix of at least 2*2 and disposed on the substrate, wherein the 2*2 means that there are at least two LED units, among the plurality of LED units, in an X-axis and a Y-axis of the substrate, respectively, and each of the plurality of LED units comprises:
a first LED;
a second LED installed on a side of the first LED, wherein the first LED and the second LED are arranged in a matrix of 1*2 in the X-axis, the 1*2 means that the first LED and the second LED are arranged in the X-axis, the first LED and the second LED have a beam angle greater than or equal to 90 degrees, each of the plurality of LED units has one or more emitting light colors based on light colors of the first LED and the second LED, a length of each first LED and each second LED in the Y-axis is greater than or equal to a length of each first LED and each second LED in the X-axis, and a length of each first LED and each second LED in a Z-axis is more than 10 μm; and
at least one first light replenishment section formed and sandwiched by the first LED and the second LED;
at least two second light replenishment sections formed and sandwiched between any two adjacent LED units, among the plurality of LED units, in the X-axis;
at least two third light replenishment sections formed and sandwiched between any two adjacent LED units, among the plurality of LED units, in the Y-axis, wherein each of the at least two third light replenishment sections is greater than each of the at least two second light replenishment sections, and each of the at least two second light replenishment sections is greater than or equal to the at least one first light replenishment section;
at least one fourth light replenishment section formed and sandwiched between the at least two second light replenishment sections and the at least two third light replenishment sections;
a first reflective gel filled in the at least one first light replenishment section, the at least two second light replenishment sections, the at least two third light replenishment sections, and the at least one fourth light replenishment section, wherein the first reflective gel has a reflectivity greater than 50% relative to light with a wavelength of 420 nm˜700 nm; and
a second reflective gel filled between an edge of the substrate and adjacent LED units, between an edge of the substrate and the at least two second light replenishment sections, and between an edge of the substrate and the at least two third light replenishment sections, wherein the second reflective gel has a reflectivity greater than 50% relative to the light with a wavelength of 420 nm˜700 nm, and the reflectivity of the first reflective gel relative to the light with the wavelength of 420 nm˜700 nm is greater than or equal to the reflectivity of the second reflective gel relative to the light with the wavelength of 420 nm˜700 nm,
wherein the length of each first LED and each second LED in the X-axis is 70˜125 μm, the length of each first LED and each second LED in the Y-axis is 115˜230 μm, an area of each of the at least one first light replenishment section is equal to 0.04˜0.86 times an area of the first LED or the second LED, an area of each of the at least two second light replenishment sections is equal to 0.04˜3.44 times the area of the first LED or the second LED, an area of each of the at least two third light replenishment sections is equal to 0.08˜6 times the area of the first LED or the second LED.

2. The mini LED light panel according to claim 1, wherein the first reflective gel and the second reflective gel are integrally formed after:
reflective gel materials coated into areas of the plurality of LED units, the at least two second light replenishment sections, the at least two third light replenishment sections, the at least one fourth light replenishment section, and between the edge of the substrate and the adjacent LED units, and
adjusting a thickness of the reflective gel materials corresponding to positions of the first LED and the second LED, and
lengths of the first reflective gel and the second reflective gel and the lengths of the first LED and the second LED in the Z-axis are consistent with each other.

3. The mini LED light panel according to claim 1, wherein each of the plurality of LED units further comprises a third LED and two first light replenishment sections, including the at least one first light replenishment section, the third LED is installed to a side of the first LED or the second LED to form one of the two first light replenishment sections, and the third LED, the first LED, and the second LED, in the X-axis, are arranged into a matrix of 1*3, wherein the 1*3 means that the first LED, the second LED, and the third LED are arranged in the X-axis, the third LED has a beam angle greater than or equal to 90 degrees, lengths of the third LED in the X-axis and in the Y-axis is equal to 25˜500 μm, respectively, the length of the third LED in the Y-axis is greater than or equal to the length of the third LED in the X-axis, a length of the third LED in the Z-axis is more than 10 μm, and the length of the third LED in the Z-axis is consistent with the length of the first LED or the second LED in the Z-axis.

4. A mini LED light panel used as a display and filled with reflective gel to enhance luminosity, comprising:
a substrate;
a plurality of LED units arranged in a matrix of at least 2*2 on the substrate, wherein the 2*2 means that there are at least two LED units, among the plurality of LED units, in an X-axis and a Y-axis of the substrate respectively, and each of the plurality of LED units comprises:
a first LED;
a second LED installed on a side of the first LED;
a third LED installed on a side of the first LED or the second LED, wherein the first LED, the second LED, and the third LED are arranged in a matrix of 1*3 in the X-axis, the 1*3 means that the first LED, the second LED, and the third LED are arranged in the X-axis, the first LED, the second LED, and the third LED have a beam angle greater than or equal to 90 degrees, respectively, each of the plurality of LED units has one or more emitting light colors based on light colors of the first LED and the second LED, a length of each first LED and each second LED in a Z-axis is more than 10 μm, a length of the third LED in the Z-axis is consistent with the length of the first LED or the second LED in the Z-axis, the length of each first LED, each second LED, and each third LED in the Y-axis is greater than or equal to the length of each first LED, each second LED and each third LED in the X-axis; and
two first light replenishment sections formed and sandwiched by the first LED, the second LED, and the third LED;
at least two second light replenishment sections formed and sandwiched between any two adjacent LED units in the X-axis;
at least two third light replenishment sections formed and sandwiched by any two adjacent LED units in the Y-axis, wherein each of the at least two third light replenishment sections is greater than each of the at least two second light replenishment sections, and each of the at least two second light replenishment sections is greater than or equal to each of the two first light replenishment sections;
at least one fourth light replenishment section formed and sandwiched by the at least two second light replenishment sections and the at least two third light replenishment sections;
a first reflective gel filled into the two first light replenishment sections, the at least two second light replenishment sections, the at least two third light replenishment sections, and the at least one fourth light replenishment section, wherein the first reflective gel has a reflectivity greater than 50% relative to light with a wavelength of 420 nm˜700 nm; and
a second reflective gel filled between an edge of the substrate and adjacent LED units, between an edge of the substrate and the at least two second light replenishment sections, and between an edge of the substrate and the at least two third light replenishment sections, wherein the second reflective gel has a reflectivity greater than 50% relative to the light with the wavelength of 420 nm˜700 nm, and the reflectivity of the first reflective gel relative to the light with the wavelength of 420 nm˜700 nm is greater than or equal to the reflectivity of the second reflective gel relative to the light with the wavelength of 420 nm˜700 nm,
wherein the length of each first LED, each second LED, and each third LED in the X-axis is 25˜110 μm, the length of each first LED, each second LED, and each third LED in the Y-axis is 50˜210 μm, an area of each of the two first light replenishment sections is equal to 0.2˜5.4 times an area of the first LED, the second LED, or the third LED, an area of each of the at least two second light replenishment sections is equal to 0.2˜57 times the area of the first LED, the second LED, or the third LED, and an area of each of the at least two third light replenishment sections is equal to 5˜119 times the area of the first LED, the second LED, or the third LED.

5. The mini LED light panel according to claim 4, wherein the first reflective gel and the second reflective gel are integrally formed after:
reflective gel materials coated onto the plurality of LED units, the at least two second light replenishment sections, the at least two third light replenishment sections, the at least one fourth light replenishment section, and between the edge of the substrate and the adjacent LED units, and
adjusting a thickness of reflective gel materials corresponding to positions of the first LED, the second LED, and the third LED, and
lengths of the first reflective gel and the second reflective gel in the Z-axis are consistent with the lengths of the first LED and the second LED.

6. The mini LED light panel according to claim 1, further comprising a protective part covered on the plurality of LED units, the first reflective gel, and the second reflective gel, wherein the protective part has a penetration rate greater than 0.5%.

7. The mini LED light panel according to claim 4, further comprising a protective part covered on the plurality of LED units, the first reflective gel, and the second reflective gel, wherein the protective part has a penetration rate greater than 0.5%.

8. The mini LED light panel according to claim 1, further comprising a light adjustment part covered onto the plurality of LED units, the first reflective gel, and the second reflective gel, wherein the light adjustment part is a single-layer structure or a multi-layer structure.

9. The mini LED light panel according to claim 4, further comprising a light adjustment part covered onto the plurality of LED units, the first reflective gel, and the second reflective gel, wherein the light adjustment part is a single-layer structure or a multi-layer structure.

10. The mini LED light panel according to claim 1, further comprising a protective part and a light adjustment part, wherein
the light adjustment part is a single-layer structure or a multi-layer structure covered onto the plurality of LED units, the first reflective gel, and the second reflective gel, and
the protective part is covered onto the light adjustment part and has a penetration rate greater than 0.5%.

11. The mini LED light panel according to claim 4, further comprising a protective part and a light adjustment part, wherein
the light adjustment part is a single-layer structure or a multi-layer structure covered onto the plurality of LED units, the first reflective gel, and the second reflective gel, and
the protective part is covered onto the light adjustment part and has a penetration rate greater than 0.5%.

12. A mini LED display with visually concealed splicing lines and a high brightness compensation, comprising:
a plurality of mini LED light panels, including the mini LED light panel according to claim 1, and the plurality of mini LED light panels being spliced to form a display panel;
5 and a frame mounted onto a periphery of the display panel.

13. A mini LED display with visually concealed splicing lines and a high brightness compensation, comprising:
a plurality of mini LED light panels, including the mini LED light panel according to 10 claim 4, and the plurality of mini LED light panels being spliced to form a display panel; and
a frame mounted onto a periphery of the display panel.
